(19) United States
(12) Patent Application Publication
(10) Pub. No.: US 2019/0302346 A1
(43) Pub. Date: Oct. 3, 2019

(54) OPTICAL PHOTORESIST PHOTOLITHOGRAPHY METHOD AND TRANSPARENT ILLUMINATION DEVICE

(71) Applicant: NanoPath, Inc., Leominster, MA (US)

(72) Inventor: Kevin Donahue, Harvard, MA (US)

(73) Assignee: NanoPath, Inc., Leominster, MA (US)

(21) Appl. No.: 16/373,176

(22) Filed: Apr. 2, 2019

Related U.S. Application Data
(60) Provisional application No. 62/652,175, filed on Apr. 3, 2018.

(51) Int. Cl. F21V 8/00; G03F 7/16

(52) U.S. Cl. CPC G02B 6/0051; G03F 7/164; G02B 6/0055

(57) ABSTRACT

This disclosure provides systems and methods for fabricating a transparent display device. The display device can include a light guide having a first surface for illumination and a second surface, positioned opposite the first surface. The second surface can be a non-illuminated surface. The display device can include a plurality of one-way light emitting pixels positioned on the second surface of the light guide and configured to frustrate total internal reflection of light within the light guide. The plurality of pixels can each include a light-diffusive layer and light-reflective layer. The display device can include a light source configured to introduce light into an edge of the light guide to cause the plurality of pixels to emit at least a portion of the light through the first surface of the light guide.

### RELATED APPLICATIONS

This application claims priority to U.S. Provisional Patent App. No. 62/652,175, filed on Apr. 3, 2018 and entitled “OPTICAL PHOTORESIST PHOTOLITHOGRAPHY METHOD AND TRANSPARENT ILLUMINATION DEVICE,” which is incorporated by reference herein in its entirety.

### FIELD OF DISCLOSURE

Systems and method of the present disclosure are directed to optical devices.

### BACKGROUND

Displays and other optical devices can make use of a light guide that is illuminated from one side. In some instances, such devices can display an image from a viewing side of the device, and may appear transparent from a non-viewing side. This phenomenon can be referred to as one-way see-through illumination or transparent illumination.

### SUMMARY

Light-curable optically transparent materials, or transparent varnishes, can be used to coat printed materials. Such coatings can be used to provide protection from scratching, to enhance clarity, or to prevent damage from ambient ultraviolet (UV) light. Some UV-curable varnishes can be composed of a monomer such as an acrylate, a photo initiator that promotes the cross linkage of the selected monomer upon exposure to UV light, and an oligomer to ensure flexibility. Many variations of this formulation exist and may be selected or configured to achieve desired properties of the resultant optical coating.

This disclosure describes a light-curable (e.g., UV-curable) optical coating that can be used as a photoresist to impart optical characteristics to the surface of an optical material, such as a sheet of glass or clear plastic. In some implementations, a device fabricated according to the techniques of this disclosure can be used to provide transparent illumination. For example, a device can be illuminated from one side, but may appear transparent when viewed from an opposite side.

In some aspects, this disclosure describes a device and methods for generating transparent illumination, or other optical effects, via the frustration of total internal reflection in a light guide. In some implementations, a device can use a light guide having a surface containing one-way light emitting pixels. Methods used to render these pixels on the light guide surface can make use of semiconductor-scale photolithography that can use a photoresist that yields a light-diffusive pixel layer capable of producing illumination by the frustration of total internal reflection of light within the light guide.

In some implementations, frustration of total internal reflection can be enabled by use of a photoresist that contains light-diffusive particles. In some implementations, after development by an isopropyl alcohol (IPA) rinse or other means, such a light-diffusive photoresist can impart a light-diffusive pattern, composed of hardened light-diffusive photoresist, on the surface of a light guide. This pattern can then be capped with a light-reflective material in a secondary process to produce a pixel pattern that emits light in one direction, thereby producing transparent illumination by frustration of the total internal reflection of light that has been edge-injected into the light guide.

At least one aspect of this disclosure is directed to a transparent display device. The display device can include a light guide having a first surface for illumination and a second surface, positioned opposite the first surface. The second surface can be a non-illuminated surface. The display device can include a plurality of one-way light emitting pixels positioned on the second surface of the light guide and configured to frustrate total internal reflection of light within the light guide. The plurality of pixels can each include a light-diffusive layer and light-reflective layer. The display device can include a light source configured to introduce light into an edge of the light guide to cause the plurality of pixels to emit at least a portion of the light through the first surface of the light guide.

In some implementations, the light-diffusive layer of each pixel of the plurality of pixels can be a photoresist containing light-diffusive particles. In some implementations, the light-diffusive particles can be at least one light-reflecting material. In some implementations, the at least one light-reflecting material of the light-diffusive particles can be aluminum. In some implementations, the light-diffusive particles can be at least one light-reactive material. In some implementations, the at least one light-reactive material of the light-diffusive particles can be at least one of a photochromic material, a fluorescent material, or a phosphorescent material. In some implementations, the light-diffusive particles can be titanium dioxide.

In some implementations, the light guide can include one of glass or transparent plastic. In some implementations, the plurality of pixels can be arranged in a predetermined pattern on the second surface of the light guide.

In some implementations, the light source can include one or more light emitting diodes (LEDs). In some implementations, the light source can be configured to introduce ultraviolet (UV) light into the edge of the light guide.

Another aspect of this disclosure is directed to a method of producing a display device. The method can include providing a light guide. The method can include coating a first surface of the light guide with a first photoresist layer containing light diffusive-particles capable of frustrating total internal reflection of injected light in the light guide to cause at least a portion of the injected light to be emitted from the light guide. The method can include depositing a first exposure mask over the first photoresist layer. The method can include exposing unmasked portions of the first photoresist layer to ultraviolet (UV) light to solidify the unmasked portions of the first photoresist layer to form a plurality of light-diffusing pixels comprising the solidified portions of the first photoresist layer. The method can include depositing a layer of light blocking material over the solidified portions of the first photoresist layer.

In some implementations, the method can include removing unexposed portions of the first photoresist layer.

In some implementations, the layer of light blocking material can be a second photoresist layer. In some implementations, the method can include depositing a second exposure mask over the second photoresist layer, such that unmasked portions of the second photoresist layer correspond to the solidified portions of the first photoresist layer. In some implementations, the method can include exposing the unmasked portions of the second photoresist layer to UV light solidify the unmasked portions of the second photoresist layer.

In some implementations, the method can include depositing a second photoresist layer over the solidified portions of the first photoresist layer. The second photoresist layer may not include light-dispersing particles. In some implementations, the method can include depositing a second exposure mask over the second photoresist layer, such that unmasked portions of the second photoresist layer correspond to the solidified portions of the first photoresist layer. In some implementations, the method can include exposing the unmasked portions of the second photoresist layer to UV light solidify the unmasked portions of the second photoresist layer. Each solidified portion of the second photoresist layer can form a well around a respective one of the solidified portions of the first photoresist layer. In some implementations, the method can include depositing the layer of light blocking material over the wells formed by the solidified portions of the second photoresist layer.

In some implementations, depositing the layer of light blocking material can include depositing a layer of metal. In some implementations, the light-diffusive particles contained in the first photoresist layer can be at least one light-reflecting material. In some implementations, the light-diffusive particles contained in the first photoresist layer can be at least one light-reactive material. In some implementations, the at least one light-reactive material of the light-diffusive particles can be at least one of a photochromic material, a fluorescent material, or a phosphorescent material.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a cross-sectional view of a device for providing transparent illumination, according to an illustrative implementation.

FIG. 2 is a cross-sectional view of a device for providing transparent illumination, according to an illustrative implementation.

FIG. 3 is a flowchart of an example method for producing a device, according to an illustrative implementation.

FIGS. 4A-4C show stages of construction of a device that can be manufactured according to the method of FIG. 3, according to an illustrative implementation.

FIGS. 5A-5C show stages of construction of a device that can be manufactured according to the method of FIG. 3, according to an illustrative implementation.

FIGS. 6A-6C show stages of construction of a device that can be manufactured according to the method of FIG. 3, according to an illustrative implementation.

FIG. 7 is a cross-sectional view of a device for providing transparent illumination, according to an illustrative implementation.

The details of various embodiments of the methods and systems are set forth in the accompanying drawings and the description below.

### DETAILED DESCRIPTION

This disclosure describes a light-curable (e.g., UV-curable) optical coating that can be used as a photoresist to impart optical characteristics to the surface of an optical material, such as a sheet of glass or clear plastic. In some implementations, a device fabricated according to the techniques of this disclosure can be used to provide transparent illumination. For example, a device can be illuminated from one side, but may appear transparent when viewed from an opposite side.

In some aspects, this disclosure describes a device and methods for generating transparent illumination, or other optical effects, via the frustration of total internal reflection in a light guide. In some implementations, a device can use a light guide having a surface containing one-way light emitting pixels. Methods used to render these pixels on the light guide surface can make use of semiconductor-scale photolithography that can use a photoresist that yields a light-diffusive pixel layer capable of producing illumination by the frustration of total internal reflection of light within the light guide.

In some implementations, frustration of total internal reflection can be enabled by use of a photoresist that contains light-diffusive particles. In some implementations, after development by an isopropyl alcohol (IPA) rinse or other means, such a light-diffusive photoresist can impart a light-diffusive pattern, composed of hardened light-diffusive photoresist, on the surface of a light guide. This pattern can then be capped with a light-reflective material in a secondary process to produce a pixel pattern that emits light in one direction, thereby producing transparent illumination by frustration of the total internal reflection of light that has been edge-injected into the light guide.

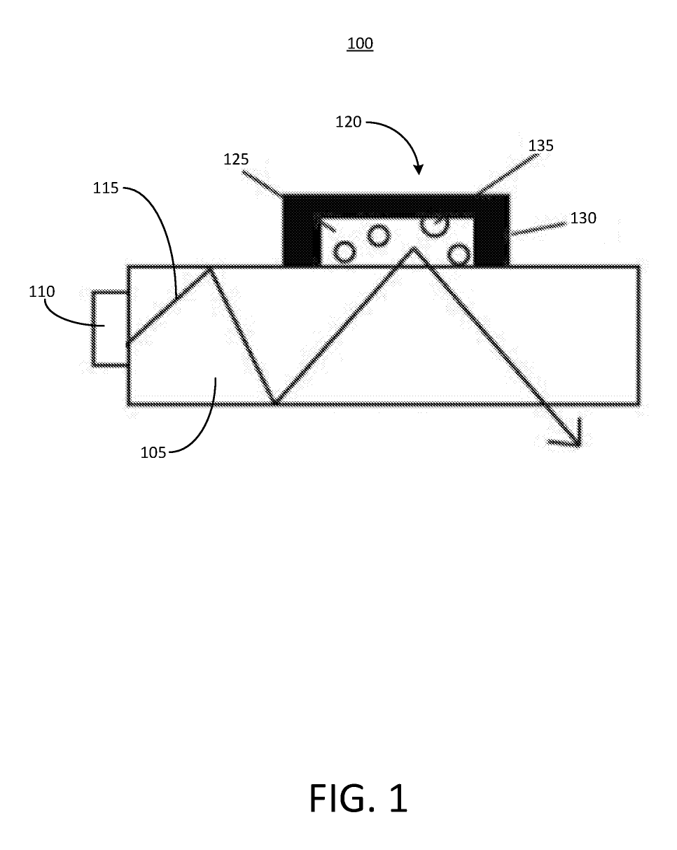

FIG. 1 is a cross-sectional view of a device 100 for providing transparent illumination, according to an illustrative implementation. The device 100 can include a light guide 105. A light source 110 can be coupled with an edge of the light guide 105. The light source 110 can be configured to inject or introduce light, such as the light ray 115, into the edge of the light guide 105. In some implementations, the light source 110 can be configured to produce UV light into the light guide 105. In some implementations, the light guide 105 can be configured to provide total internal reflection of the light injected by the light source 110.

The device 100 can also include a light-emitting pixel 120. In some implementations, the pixel 120 can be configured to frustrate total internal reflection of light within the light guide 105 to cause at least a portion of the light to be emitted from the light guide 105, as illustrated by the light ray 115. The pixel 120 can be formed from a light-diffusive layer 125, which can be capped by a light-reflective layer 130. The light-diffusive layer 125 can contain light-diffusive particles 135. In some implementations, the light-diffusive layer 125 can be a hardened layer of light-diffusive photoresist that has been patterned to form the pixel 120 on the surface of the light guide 105. In some implementations, the surface of the light guide 105 can also include additional pixels similar to the pixel 120, and the pixels may be arranged in a predetermined pattern across the surface of the light guide 105. In some implementations, the light-diffusive particles 135 of the light-diffusive layer 125 can be or can include a light reflecting material, such as aluminum. In some implementations, the light-diffusive particles 135 of the light-diffusive layer 125 can be or can include a light-reactive material, such as a photochromic material, a fluorescent material, or a phosphorescent material. In some implementations, the light-diffusive particles 135 of the light-diffusive layer 125 can be or can include a light-refractive material, such as titanium dioxide. In some implementations, the light-reflective layer 130 can be formed from a reflective metal, such as aluminum.

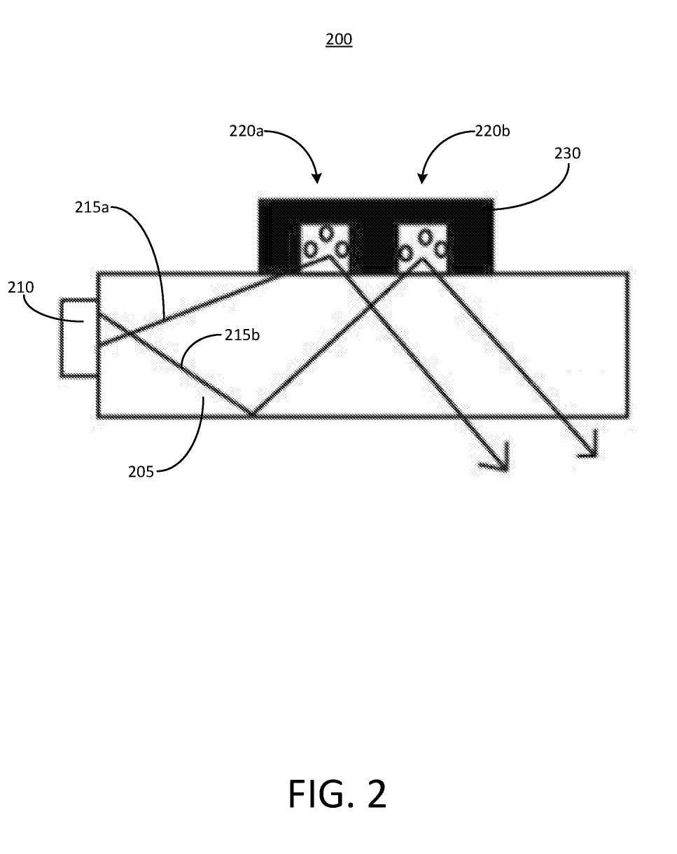

FIG. 2 is a cross-sectional view of a device 200 for providing transparent illumination, according to an illustrative implementation. The device 200 is similar to the device 100 of FIG. 1, and like reference numeral refer to like elements. For example, the device 200 includes a light guide 205 that can receive light (e.g., the light rays 215a and 215b) from a light source 210. The device 200 differs from the device 100 in that the device 200 includes two pixels 220a and 220b, both of which are capped by a common light-reflecting layer 230. The structures of the pixels 220a and 220b can be similar to that of the pixel 120 of FIG. 1. For example, each pixel 220a and 220b may include a light-diffusive material selected or configured to frustrate total internal reflection of light within the light guide 205. Thus, the pixel 220a can cause the light ray 215a to escape from the light guide 205, and the pixel 220b can cause the light ray 215b to escape from the light guide 205. In some implementations, both of the pixels 220a and 220b can be formed through one or more common steps. That is, the pixels 220a and 220b can be formed simultaneously through a single set of steps that may include depositing and patterning the light-diffusing material (e.g., a light-diffusing photoresist layer) that forms the pixels. Similarly, the layer of light-reflecting material 230 can be deposited over both pixels 220a and 220b in a single manufacturing step in some implementations.

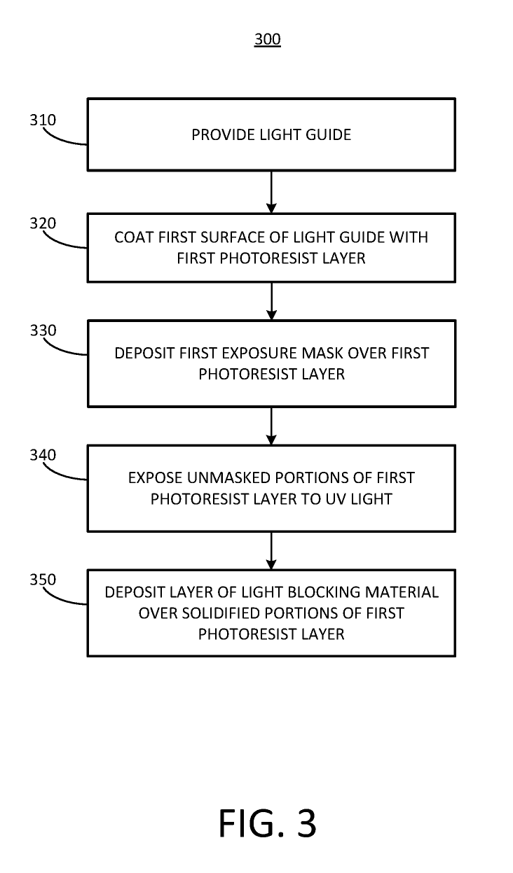

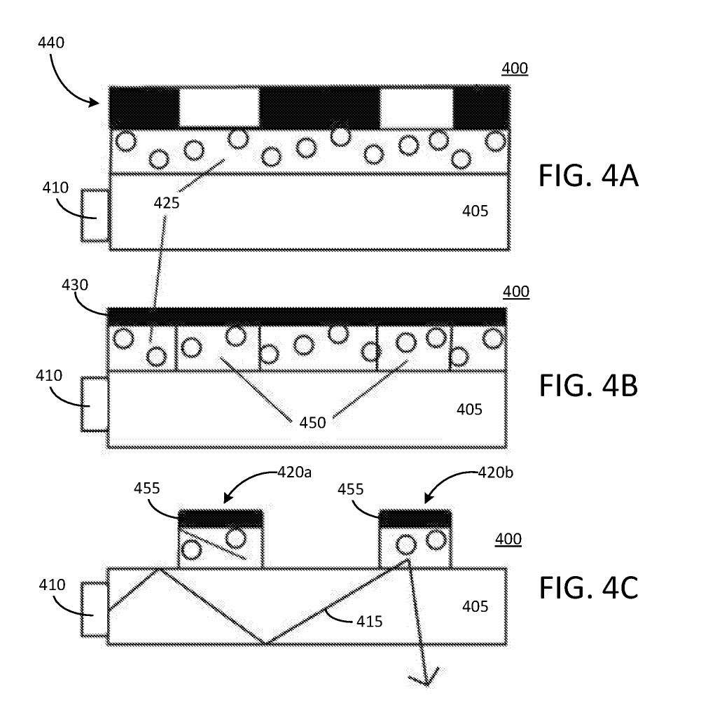

FIG. 3 is a flowchart of an example method 300 for producing a device, according to an illustrative implementation. In some implementations, the device formed using the method 300 can be similar to the devices 100 and 200 shown in FIGS. 1 and 2, respectively. FIGS. 4A-4C show stages of construction of a device 400 that can be manufactured according to the method 300 of FIG. 3, according to an illustrative implementation. FIGS. 3 and 4A-4C are therefore described together below.

Referring now to FIG. 3, the method 300 can include providing a light guide (BLOCK 310). For example, the light guide can be the light guide 405 of FIGS. 4A-4C. the light guide 405 can be similar to the light guides 105 and 205 of FIGS. 1 and 2, respectively. In some implementations, a light source 410 can be coupled with an edge of the light guide 405 and configured to introduce light, such as UV light, into the light guide 405. The method 300 can include coating a first surface of the light guide with a first photoresist layer containing light diffusive-particles (BLOCK 320). For example, the first photoresist layer 425 is shown in FIGS. 4A and 4B. In some implementations, the first photoresist layer 425 can be deposited using a spin coating technique. In some implementations, the first photoresist layer 425 can be similar to the light-diffusive layer 125 shown in FIG. 1. In some implementations, the first photoresist layer 425 can be capable of frustrating total internal reflection of injected light in the light guide to cause at least a portion of the injected light to be emitted from the light guide 405. For example, the first photoresist layer 425 can include light-diffusing particles to frustrate total internal reflection.

The method 300 can include depositing a first exposure mask over the first photoresist layer (BLOCK 330). The exposure mask 440 is shown in FIG. 4A. In some implementations, exposure mask 440 can mask or block portions of the underlying first photoresist layer 425, thereby shielding the masked portions of the photoresist layer 425 from exposure to a light from above. In FIG. 4A, the dark portions of the exposure mask 440 can correspond to masked regions, while the light portions of the exposure mask 440 can correspond to unmasked or exposed regions. The method 300 can include exposing unmasked portions of the first photoresist layer to ultraviolet (UV) light to solidify the unmasked portions of the first photoresist layer (BLOCK 340). The results of this stage are shown in FIG. 4B, in which the regions 450 of the first photoresist layer 425 are solidified, and the remaining regions are not solidified. In some implementations, the solidified regions of the first photoresist layer 425 can form a plurality of light-diffusing pixels.

The method can include depositing a layer of light blocking material over the solidified portions of the first photoresist layer (BLOCK 350). The results of this stage are shown in FIG. 4C, in which the light blocking material 455 covers the solidified portions of the photoresist layer, thereby forming the pixels 420a and 420b. In some implementations, the pixels 420a and 420b can be similar to the pixel 120 of FIG. 1. For example, the pixels 420a and 420b can be configured to frustrate total internal reflection of light within the light guide 405, as illustrated by the light ray 415 that reflects from the pixel 420b and leaves the light guide 405.

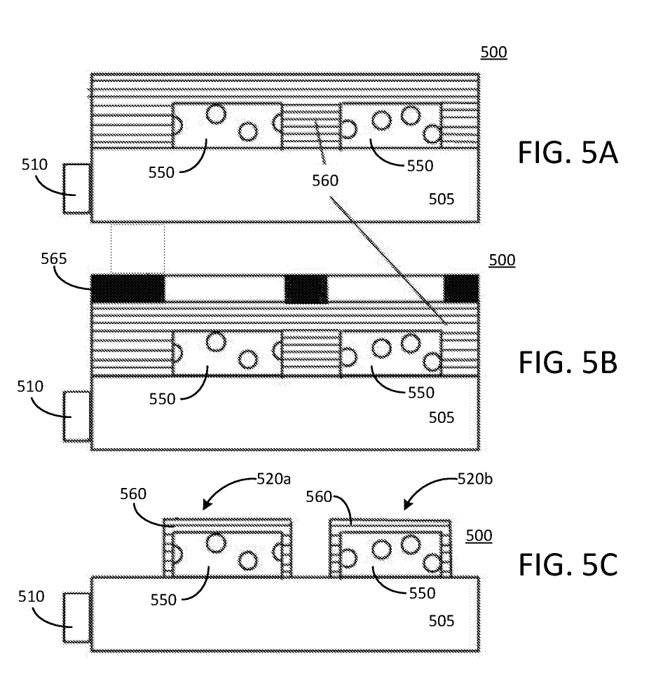

FIGS. 5A-5C show stages of construction of a device 500 that can be manufactured according to the method of FIG. 3, according to an illustrative implementation. In some implementations, portions of the device 500 can be formed using steps similar to those described above and shown in FIGS. 4A-4C. For example, the device 500 can include a light guide 505 and a light source 510. The solidified regions 550 of the first photoresist layer on the surface of the light guide 505 can correspond to the solidified regions 450 shown in FIG. 4, and can be formed in a similar manner.

The device 500 differs from the device 400 in that a second photoresist layer 560 can be deposited over the solidified regions 550 of the first photoresist layer. In some implementations, the second photoresist layer 560 can be a light-blocking layer. For example, the second photo-resist layer 560 can have light-reflecting properties. Deposition of the second photoresist layer 560 is depicted in FIG. 5A. After the second photoresist layer 560 is deposited, a second exposure mask 565 can be deposited over the second photoresist layer 560. The second exposure mask 565 is shown in FIG. 5B.

In some implementations, the exposure mask 565 can mask or block portions of the underlying second photoresist layer 560, thereby shielding the masked portions of the second photoresist layer 560 from exposure to a light from above. In FIG. 5B, the dark portions of the exposure mask 565 can correspond to masked regions, while the light portions of the exposure mask 565 can correspond to unmasked or exposed regions. The unmasked portions of the second photoresist layer 560 can be exposed to ultraviolet (UV) light to solidify the unmasked portions of the second photoresist layer 560. The results of this stage are shown in FIG. 5C. As shown, this can result in pixels 520a and 520b, which can be similar to the pixels 420a and 420b of FIG. 4. For example, the remaining second photoresist layer 560 can serve a function similar to that of the light blocking material 455 that caps the pixels 420a and 420b in FIG. 4.

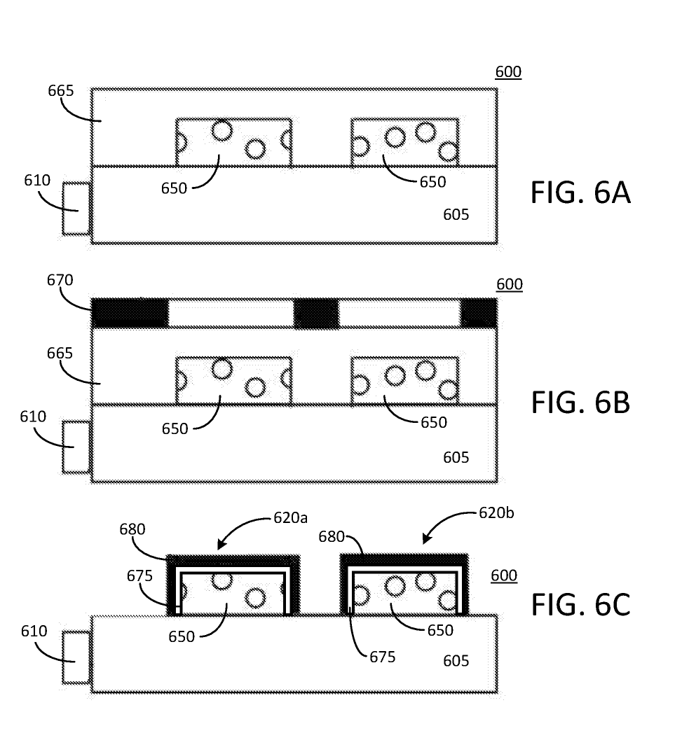

FIGS. 6A-6C show stages of construction of a device 600 that can be manufactured according to the method of FIG. 3, according to an illustrative implementation. In some implementations, portions of the device 600 can be formed using steps similar to those described above and shown in FIGS. 4A-4C. For example, the device 600 can include a light guide 605 and a light source 610. The solidified regions 650 of the first photoresist layer on the surface of the light guide 605 can correspond to the solidified regions 450 shown in FIG. 4, and can be formed in a similar manner.

The device 600 differs from the device 400 in that a second photoresist layer 665 can be deposited over the solidified regions 650 of the first photoresist layer. In some implementations, the second photoresist layer 665 may not be a light-blocking layer. For example, the second photo-resist layer 665 may not include any particles that are light-dispersive. Deposition of the second photoresist layer 665 is depicted in FIG. 6A. After the second photoresist layer 665 is deposited, a second exposure mask 670 can be deposited over the second photoresist layer 665. The second exposure mask 670 is shown in FIG. 6B.

In some implementations, the exposure mask 670 can mask or block portions of the underlying second photoresist layer 665, thereby shielding the masked portions of the second photoresist layer 665 from exposure to a light from above. In FIG. 5B, the dark portions of the exposure mask 670 can correspond to masked regions, while the light portions of the exposure mask 670 can correspond to unmasked or exposed regions. The unmasked portions of the second photoresist layer 665 can be exposed to ultraviolet (UV) light to solidify the unmasked portions of the second photoresist layer 665. The results of this stage are shown in FIG. 6C, in which each of the solidified regions 650 of the first photoresist layer is surrounded by a “well” 675 formed from the solidified second photoresist layer 665. Also shown in FIG. 6C is a light blocking layer 680, which may be formed from a light reflecting material. In some implementations, because the wells 675 may not block light, the additional light blocking layer 680 may be deposited over the wells 675 to cap the pixels 620a and 620b. In some implementations, the wells 675 can help to promote adhesion of the light blocking layer 680 to the pixels 620a and 620b. In some implementations, the light blocking layer 680 can be a metal layer. In some implementations, the light blocking layer 680 can serve a function similar to that of the light blocking material 455 that caps the pixels 420a and 420b in FIG. 4.

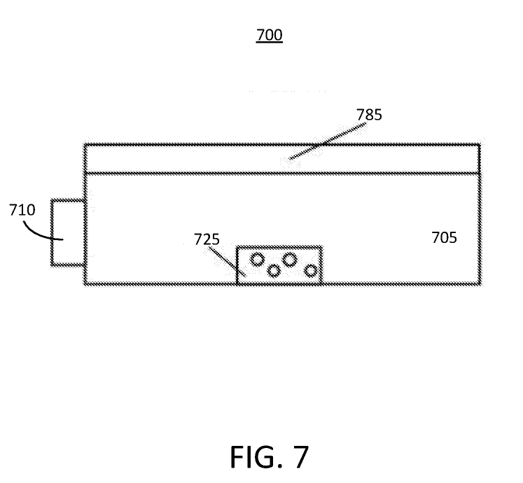

FIG. 7 is a cross-sectional view of a device 700 for providing transparent illumination, according to an illustrative implementation. The device 700 is similar to the devices 400, 500, and 600 of FIGS. 4A-4C, 5A-5C, and 6A-6C, respectively, and like reference numeral refer to like elements. For example, the device 700 includes a light guide 705 and a light source 710 coupled to an edge of the light guide 705. The device 705 differs from the other devices in that the layer of light-diffusing material 725 is positioned on the non-illuminated side of the device, rather than on the illuminated side of the device. As a result of this arrangement, one or more layers of photoresist, such as the photoresist layer 785, can be exposed to light via frustration of total internal reflection of light injected into the light guide 705 by the light source 710. For example, the light-diffusing material 705 can be configured to frustrate total internal reflection within the light guide and to cause at least some of the injected light to contact the photoresist layer 785. Thus, the photoresist layer 785 can be exposed by activating the light source 710, rather than using an external light source.

The embodiments of the inventive concepts disclosed herein have been described in detail with particular reference to preferred embodiments thereof, but it will be understood by those skilled in the art that variations and modifications can be effected within the spirit and scope of the inventive concepts.

Embodiments of the inventive concepts disclosed herein have been described with reference to drawings. The drawings illustrate certain details of specific embodiments that implement systems and methods of the present disclosure. However, describing the embodiments with drawings should not be construed as imposing any limitations that may be present in the drawings.

The foregoing description of embodiments has been presented for the purposes of illustration and description. It is not intended to be exhaustive or to limit the subject matter to the precise form disclosed, and modifications and variations are possible in light of the above teachings or may be acquired from practice of the subject matter disclosed herein. The embodiments were chosen and described in order to explain the principals of the disclosed subject matter and its practical application to enable one skilled in the art to utilize the disclosed subject matter in various embodiments with various modification as are suited to the particular use contemplated. Other substitutions, modifications, changes and omissions may be made in the design, operating conditions and arrangement of the embodiments without departing from the scope of the presently disclosed subject matter.

What is claimed is:

1. A transparent display device comprising:
a light guide having a first surface for illumination and a second surface, positioned opposite the first surface, the second surface comprising a non-illuminated surface;
a plurality of one-way light emitting pixels positioned on the second surface of the light guide and configured to frustrate total internal reflection of light within the light guide, the plurality of pixels each comprising a light-diffusive layer and light-reflective layer; and
a light source configured to introduce light into an edge of the light guide to cause the plurality of pixels to emit at least a portion of the light through the first surface of the light guide.

2. The transparent display device of claim 1, wherein the light-diffusive layer of each pixel of the plurality of pixels comprises a photoresist containing light-diffusive particles.

3. The transparent display device of claim 2, wherein the light-diffusive particles comprise at least one light-reflecting material.

4. The transparent display device of claim 3, wherein the at least one light-reflecting material of the light-diffusive particles comprises aluminum.

5. The transparent display device of claim 2, wherein the light-diffusive particles comprise at least one light-reactive material.

6. The transparent display device of claim 5, wherein the at least one light-reactive material of the light-diffusive particles comprises at least one of a photochromic material, a fluorescent material, or a phosphorescent material.

7. The transparent display device of claim 2, wherein the light-diffusive particles comprise titanium dioxide.

8. The transparent display device of claim 1, wherein the light guide comprises one of glass or transparent plastic.

9. The transparent display device of claim 1, wherein the plurality of pixels are arranged in a predetermined pattern on the second surface of the light guide.

10. The transparent display device of claim 1, wherein the light source comprises one or more light emitting diodes (LEDs).

11. The transparent display device of claim 1, wherein the light source is configured to introduce ultraviolet (UV) light into the edge of the light guide.

12. A method of producing a display device, the method comprising:
providing a light guide;
coating a first surface of the light guide with a first photoresist layer containing light diffusive-particles capable of frustrating total internal reflection of injected light in the light guide to cause at least a portion of the injected light to be emitted from the light guide;
depositing a first exposure mask over the first photoresist layer;
exposing unmasked portions of the first photoresist layer to ultraviolet (UV) light to solidify the unmasked portions of the first photoresist layer to form a plurality of light-diffusing pixels comprising the solidified portions of the first photoresist layer; and
depositing a layer of light blocking material over the solidified portions of the first photoresist layer.

13. The method of claim 12, further comprising removing unexposed portions of the first photoresist layer.

14. The method of claim 12, wherein the layer of light blocking material comprises a second photoresist layer.

15. The method of claim 14, further comprising:
depositing a second exposure mask over the second photoresist layer, such that unmasked portions of the second photoresist layer correspond to the solidified portions of the first photoresist layer; and
exposing the unmasked portions of the second photoresist layer to UV light solidify the unmasked portions of the second photoresist layer.

16. The method of claim 12, further comprising:
depositing a second photoresist layer over the solidified portions of the first photoresist layer, wherein the second photoresist layer does not include light-dispersing particles; depositing a second exposure mask over the second photoresist layer, such that unmasked portions of the second photoresist layer correspond to the solidified portions of the first photoresist layer;
exposing the unmasked portions of the second photoresist layer to UV light solidify the unmasked portions of the second photoresist layer, each solidified portion of the second photoresist layer forming a well around a respective one of the solidified portions of the first photoresist layer; and
depositing the layer of light blocking material over the wells formed by the solidified portions of the second photoresist layer.

17. The method of claim 12, wherein depositing the layer of light blocking material comprises depositing a layer of metal.

18. The method of claim 12, wherein the light-diffusive particles contained in the first photoresist layer comprise at least one light-reflecting material.

19. The method of claim 12, wherein the light-diffusive particles contained in the first photoresist layer comprise at least one light-reactive material.

20. The method of claim 19, wherein the at least one light-reactive material of the light-diffusive particles comprises at least one of a photochromic material, a fluorescent material, or a phosphorescent material.
